(19) United States
(12) Patent Application Publication
(10) Pub. No.: US 2024/0037377 A1
(43) Pub. Date: Feb. 1, 2024

(54) METHOD AND APPARATUS WITH WEIGHT COMPRESSION

(71) Applicants: Samsung Electronics Co., Ltd., Suwon-si (KR); Seoul National University R&DB Foundation, Seoul (KR)

(72) Inventors: Hoon SHIN, Suwon-si (KR); Jae Wook LEE, Seoul (KR); Rihae PARK, Seoul (KR); Yeonhong PARK, Seoul (KR); Seung Yul LEE, Seoul (KR); Hyunseung LEE, Seoul (KR)

(73) Assignees: Samsung Electronics Co., Ltd., Seoul (KR); Seoul National University R&DB Foundation, Suwon-si (KR)

(21) Appl. No.: 18/345,533

(22) Filed: Jun. 30, 2023

(30) Foreign Application Priority Data
Jul. 26, 2022 (KR) 10-2022-0092353

(51) Int. Cl. G06N 3/048; G11C 11/54

(52) U.S. Cl. CPC G06N 3/048; G11C 11/54

(57) ABSTRACT

A method and apparatus are provided. The method includes reordering a plurality of filters, then based on a result of the reordering, compressing weights, among a plurality of weights of the plurality of filters, resulting in some of the plurality of weights being uncompressed weights, generating a plurality of operation unit maps by mapping the uncompressed weights to respective operation units according to a predetermined bulk unit, and mapping the plurality of operation unit maps to an array.

### CROSS-REFERENCE TO RELATED APPLICATIONS

This application claims the benefit under 35 USC § 119(a) of Korean Patent Application No. 10-2022-0092353, filed on Jul. 26, 2022, at the Korean Intellectual Property Office, the entire disclosure of which is incorporated herein by reference for all purposes.

### BACKGROUND

### 1. Field

The following description relates to a method and apparatus with weight compression.

### 2. Description of Related Art

An artificial neural network (hereinafter referred to as a “neural network”) is implemented as or by an electronic computational architecture.

A device that implements a neural network typically requires a large amount of computational power to be able to handle complex input data. As a learning capacity of the neural network increases, the connections within the neural network typically becomes more complex.

### SUMMARY

This Summary is provided to introduce a selection of concepts in a simplified form that are further described below in the Detailed Description. This Summary is not intended to identify key features or essential features of the claimed subject matter, and is not intended to be used as an aid in determining the scope of the claimed subject matter.

In one general aspect, a processor-implemented method includes reordering a plurality of filters, based on a result of the reordering, compressing weights, among a plurality of weights of the plurality of filters, resulting in some of the plurality of weights being uncompressed weights, generating a plurality of operation unit maps by mapping the uncompressed weights to respective operation units according to a predetermined bulk unit, and mapping the plurality of operation unit maps to an array.

The reordering may include determining a base filter from among the plurality of filters, calculating a compression ratio between the base filter and one or more of the plurality of filters in the bulk unit, and determining a filter paired with the base filter based on a result of the calculating, where the compressing may include compressing weights of the base filter and the paired filter that have a zero value at a same weight map position with respect to the base filter and the paired filter.

The reordering may include determining a base filter from among the plurality of filters, and determining a filter, among the plurality of filters, that when paired with the base filter weights of the paired filter and the base filter may be compressed most compared to respective pairings of the base filter with remaining filters of the plurality of filters.

The compressing of the weights may include compressing weights of a base filter and a paired filter, based on a first direction.

The compressing of the weights may include row compressing the weights of the base filter and the paired filter.

The row compressing may include compressing a row in which all elements have a predetermined weight value, among rows of the base filter and the paired filter.

The generating of the plurality of operation unit maps may include generating a first operation unit map with respect to some of the plurality of weights with respect to paired filters of the plurality of filters, and after the generation of the first operation unit map, repeating the reordering and the compressing with respect to remaining weights of the plurality of weights with respect to other paired filters, to acquire a second operation unit map, where the other paired filters include at least one same filter of the paired filters.

The method may further include acquiring index information of the plurality of filters, determining index information of the plurality of operation unit maps based on the index information of the plurality of filters, and mapping respective input activations to the array based on the index information of the plurality of operation unit maps.

The array may include a resistive random access memory (ReRAM) having a crossbar array structure.

In one general aspect, a non-transitory computer-readable storage medium is provided storing instructions that, when executed by a processor, cause the processor to perform any one, combination, or all operations or methods described herein.

In one general aspect, an apparatus includes a processor configured to reorder a plurality of filters, based on a result of the reordering, compress weights, among a plurality of weights of the plurality of filters, resulting in some of the plurality of weights being uncompressed weights, generate a plurality of operation unit maps by mapping the uncompressed weights to respective operation units according to a predetermined bulk unit, map the plurality of operation unit maps to an array.

For the reordering, the processor may be configured to determine a base filter from among the plurality of filters, calculate a compression ratio between the base filter and one or more of the plurality of filters in the bulk unit, and determine a filter paired to the base filter based on a result of the calculating, where, for the compressing, the processor may be configured to compress weights of the base filter and the paired filter that have zero value at a same weight map position with respect to the base filter and the paired filter.

For the reordering, the processor may be configured to determine a base filter from among the plurality of filters, and determine a filter, among the plurality of filters, that when paired with the base filter weights of the paired filter and the base filter may be compressed most compared to respective pairings of the base filter and remaining filters of the plurality of filters.

For the compressing, the processor may be configured to compress weights of a base filter and a paired filter, based on a first direction.

For the compressing, the processor may be configured to row compress the weights of the base filter and the paired filter.

For the compressing, the processor may be configured to compress a row in which all elements have a predetermined weight value, among rows of the base filter and the paired filter.

For the generating of the plurality of operation unit maps, the processor may be configured to generate a first operation unit map with respect to some of the plurality of weights with respect to paired filters of the plurality of filters, and after the generation of the first operation unit map, repeat the reordering and the compressing with respect to remaining weights of the plurality of weights with respect to other paired filters, to acquire a second operation unit map, where the other paired filters include at least one same filter of the paired filters.

The processor may be further configured to determine index information of the plurality of operation unit maps based on index information of the plurality of filters. For the mapping, the processor may be configured to map respective input activations to the array based on the index information of the plurality of operation unit maps and the processor may be further configured to implement a portion of a neural network to generate feature information, including application of the mapped respective input activations to the array.

In one general aspect, an apparatus includes a processor configured to perform a compression operation with respect to weights of a sparse neural network to remove zero valued weights with sub-filter granularity, including performance of a reordering of plural filters into respective first pairs, compression of zero value weights of respectively same weight map positions in each of the first pairs, performance of another reordering of the plural filters into respective second pairs, and compression of zero value weights of respectively same weight map positions in each of the second pairs.

The processor may be further configured to generate feature information by the neural network by implementing plural crossbar arrays with uncompressed weights resulting from the performed compression operation, where some of the plural crossbar arrays may be respectively mapped with different portions of uncompressed weights of a filter of the plural filters.

Other features and aspects will be apparent from the following detailed description, the drawings, and the claims.

### BRIEF DESCRIPTION OF THE DRAWINGS

FIG. 1 illustrates an example artificial neural network configuration and implementation.

FIG. 2 illustrates an example of a method of performing a neural network operation using an array.

FIG. 3 is a block diagram illustrating an example computing apparatus with weight compression.

FIG. 4 is a flowchart illustrating an example method with weight compression.

FIGS. 5A and 5B illustrate example methods with weight compression.

FIG. 6 illustrates an example method with a plural operation unit mappings to an array or respective arrays.

Throughout the drawings and the detailed description, unless otherwise described or provided, the same drawing reference numerals may be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third”, or A, B, (a), (b), and the like may be used herein to describe various members, components, regions, layers, portions, or sections, these members, components, regions, layers, portions, or sections are not to be limited by these terms. Each of these terminologies is not used to define an essence, order, or sequence of corresponding members, components, regions, layers, portions, or sections, for example, but used merely to distinguish the corresponding members, components, regions, layers, portions, or sections from other members, components, regions, layers, portions, or sections. Thus, a first member, component, region, layer, portions, or section referred to in the examples described herein may also be referred to as a second member, component, region, layer, portions, or section without departing from the teachings of the examples.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

The singular forms “a,” “an,” and “the” are Intended to refer to the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof. However, the use of the term “may” herein with respect to an example or embodiment, e.g., as to what an example or embodiment may include or implement, means that at least one example or embodiment exists where such a feature is included or implemented, while all examples are not limited thereto.

Unless otherwise defined, all terms used herein including technical or scientific terms have the same meaning as commonly understood by one of ordinary skill in the art to which examples belong and based on an understanding of the disclosure of the present application. Terms, such as those defined in commonly used dictionaries, are to be interpreted as having a meaning that is consistent with their meaning in the context of the relevant art and the disclosure of the present application, and are not to be interpreted in an idealized or overly formal sense unless expressly so defined herein.

As noted above, a device that implements a neural network typically requires a large amount of computational power to be able to handle complex input data, and as a learning capacity of the neural network increases, the connections within the neural network typically become more complex.

In addition, overfitting may occur when too much training data is used to train a neural network. Also, it is found herein that as a neural network becomes more complex, and an amount of memory allocated increases accordingly, miniaturization and commercialization of the device that implements the same may become more difficult. Accordingly, as found herein, there may be a desire for a compression approach that may help maintain performance of neural network(s) and reduce system costs of implementing the same.

The examples may be Implemented as various types of products, such as, for example, a personal computer (PC), a laptop computer, a tablet computer, a smartphone, a television (TV), a smart home appliance, an intelligent vehicle, a kiosk, and a wearable device, as non-limiting examples.

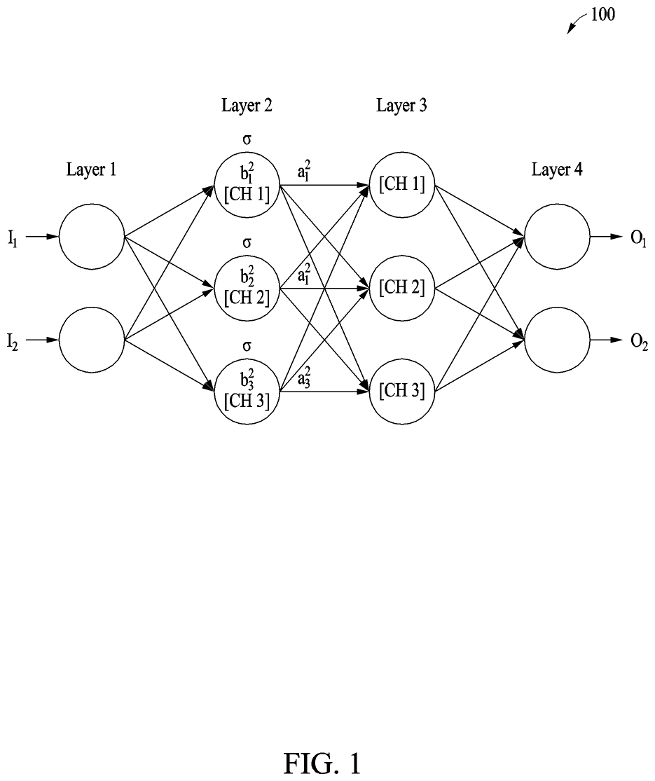

FIG. 1 illustrates an example of an artificial neural network (hereinafter referred to as “neural network”) configuration and implementation.

A deep neural network (DNN) includes a plurality of layers. For example, the DNN may include an input layer configured to receive input data, an output layer configured to output a result value derived through input data-based prediction based on learning, and a plurality of hidden layers provided between the input layer and the output layer. Convolutional neural networks (CNNs), recurrent neural networks (RNNs), and the like, are examples of DNNs used to process information.

A method of training a neural network may be referred to as deep learning. Various algorithms, for example, a CNN scheme and an RNN scheme, may be used for deep learning. Training the neural network may involve determining and updating or adjusting weights between layers, and may further or alternatively include determining and updating respective biases applied to nodes of the neural network. For example, weights of respective connections between nodes of adjacent layers may be updated during training.

Hierarchical structures and layers, including weights and biases between a plurality of neurons, may be collectively referred to as connectivity of the neural network. Training a neural network may involve constructing and learning the connectivity.

Referring to FIG. 1, an example neural network 100 may include an input layer (Layer 1), hidden layers (e.g., Layer 2 and Layer 3), and an output layer (Layer 4). The neural network may perform an operation based on received input data (e.g., I1 and I2) and generate output data (e.g., O1 and O2). As noted above, the DNN may be a CNN, an RNN, a deep belief network (DBN), a restricted Boltzmann machine (RBM), or the like, but examples are not limited thereto.

In the case of a CNN, a CNN uses a convolution operation, which is useful, for example, to find a pattern, recognize an object, face, or scene, etc., in an image. In a CNN, a filter may perform a convolution operation while traversing pixels or data of an input, e.g., in an input image, at a predetermined interval to extract features of the image and generate feature map(s) or activation map(s) using a result of the convolution operation. The filter includes weight parameters for filtering an input, and may also be referred to as a kernel. One or more layers of a neural network may each include multiple filters or kernels to be convolved over the input, and each filter or kernel may also include plural channels of filter or kernel maps, e.g., respectively corresponding to plural channels of the input. When a filter is applied to an input image, for example, the interval at which the filter moves across (or traverses) the pixels or data of the input image may be referred to as a “stride”. For example, when a stride is “2”, the filter may perform the convolution operation, move 2 spaces in the pixels or data of the input image, and perform the convolution operation again, repeating until the input image has been processed. This example may be expressed as “stride parameter=2”.

A feature map may be derived from an original image (or a feature map from a preceding layer) through convolution operation, and is typically expressed in the form of a matrix or tensor. In addition, the term “activation map” may refer to a result obtained by applying an activation function to results of weightings of the filter (for example) applied to an input feature map or previous-layer feature map. In other words, the activation map may correspond to each output result of layers of the neural network that performs such activation functions. Where “activation map” is used herein, such description may apply equally to a “feature map”, unless the context suggests otherwise. Activation maps may also be referred to as a feature vectors, feature volumes or tensors generated by a layer that imposes an activation (e.g., imposes a non-linearity into the layer results).

A shape of data finally output from the CNN may change depending on, for example, a filter size, stride, a number of filters, whether to padding is applied, and/or max pooling size applied subsequent to the convolution operation, and the like. In a convolution layer, a spatial size of a feature map resulting from application of a filter is typically less than the spatial size of data inputted to the corresponding convolution layer due to the convolution involving the filter and the strides.

Padding may be predetermined values corresponding to a designated number of pixels (e.g., “2”) added around borders of a set of data, typically a matrix. For example, when padding is set to “2”, a predetermined value (e.g., “0”) may be added to the data to add a 2-pixel thick border of a matrix of input data, e.g., a feature map outputted from a previous convolution player may have a size of 32×32, for example, before the padding is applied. Accordingly, when the padding is set to “2”, an increased size of the matrix of data may be 36×36. This example may be expressed as “padding parameter=2”. As such, a spatial size of output data in a convolution layer may be adjusted through padding.

For example, if padding is not used, data may have a decrease in its spatial size while passing through a convolution layer, and accordingly, information around corners and/or image-edges of the data may be lost or diminished. Therefore, the padding may be used to prevent the information around the corners of the data from being lost or to match a spatial size of an output in the convolution layer to a spatial size of input data expected by a next convolution layer.

With respect to FIG. 1, the neural network 100 is implemented as a DNN architecture, the neural network 100 may include more layers capable of processing valid information, and thus the neural network 100 may process more complex data sets compared to a neural network that includes only a single layer. FIG. 1 illustrates a neural network 100 including four layers, but this is merely an example, and the neural network 100 may include fewer or more layers or fewer or more channels. That is, the neural network 100 may include layers of various structures different from the one illustrated in FIG. 1.

Each of the layers included in the neural network 100 may include many nodes, which may be organized according to a plurality of channels. Each node may also be referred to as a processing element (PE), a unit, or other similar terms. For explanatory purposes, where each channel of a layer includes one node, as illustrated in FIG. 1, Layer 1 may include a single channel (node), and each of Layer 2 and Layer 3 may include three channels. However, this is merely an example, and each of the layers included in the neural network 100 may include various numbers of channels. For example, in a CNN, an input image may have a number of channels (e.g., color channels), and a volume outputted by a given layer may have a number of channels (e.g., feature maps) that may correspond to a number of filters in that given layer.

Channels included in each of the layers of the neural network 100 may be interconnected to process data. For example, a channel output by one layer may be received by the next layer for operations with respect to that channel in the next layer.

An input and an output of each of the channels may be referred to as an input activation and an output activation, respectively. An activation may be both an output of one channel at a given layer and a parameter corresponding to one of the input the channel correspondingly included in a subsequent layer. Meanwhile, the channels at a given layer may determine their respective output activations based on activations, weights, and a bias received from (or corresponding to) channels in a previous layer. Using the above explanatory example when each channel of two layers include a single node, a weight may be a parameter associated with a connection between a channel's node at a given layer and a channel's node at a following layer. The weight may be applied to an output activation from the channel's node at the given layer to calculate an output activation for the channel's node in the following layer, generally, in combination with output activations (and respectively associated weights) from other channel's node in the given layer that are connected to the channel's node in the following layer.

Convolutional layer operations of each of the channels of the values of the input and corresponding filter weights may be processed as a computational unit or processing. For example, in a neural network, when σ is an activation function, wⱼₖⁱ is a weight from a k-th node included in an i-1th layer to a j-th node included in an i-th layer, bⱼⁱ is a bias value of the j-th node included in the i-th layer, and aⱼⁱ is an activation of the j-th node of the i-th layer, the activation aⱼⁱ may be expressed as in Equation 1 below.

$${a}_{j}^{i} = σ ( {\sum }_{k} ( {w}_{jk}^{i} \times {a}_{k}^{i - 1} ) + {b}_{j}^{i} ) \qquad Equation 1$$

As illustrated in FIG. 1, an activation of a first channel (CH 1) of a first layer (Layer 1) may be represented as a₁¹. In addition, a₁² may have a value of a₁²=σ(w_{1,1}²×a₁¹+w_{1,2}²×a₂¹+b₁²) according to Equation 1. The aforementioned Equation 1 is provided as an example only to describe an activation, a weight, and a bias used for the neural network 100 to process data. The activation may be a value obtained by allowing a weighted sum of the activations received from the previous layer to pass through an activation function, such as a sigmoid function or a rectified linear unit (ReLU) function.

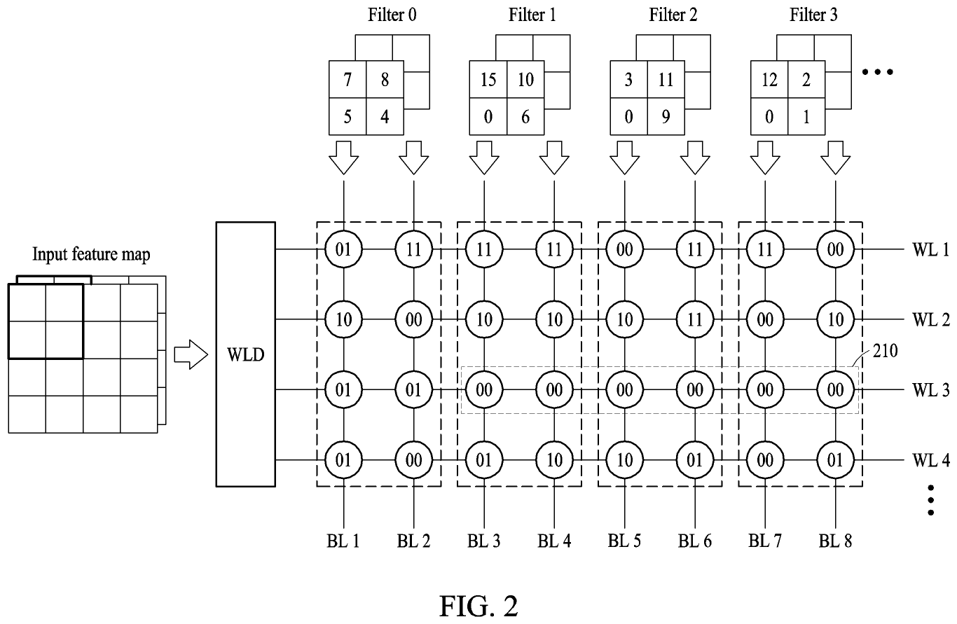

FIG. 2 illustrates an example of a method of performing a neural network operation using an array.

Referring to FIG. 2, an array may include a plurality of memory cells disposed along an input line and an output line. The plurality of memory cells may be arranged in a form of a crossbar array. The input line may be a line for receiving an input, and is shown as four word lines WL1 to WL4 in FIG. 2.

The output line may output an output signal that represents a result value or a weighted sum of a value (e.g., a multiplication and accumulation (MAC)) obtained by adding an operation result (e.g., a multiplication result) between weights of the memory cells arranged along the output line and an input value indicated by each input signal. In an example, when each weight is expressed by one or more bits, each output line may include a corresponding number of bit lines.

An array may be a resistive random access memory (ReRAM) having a crossbar array structure. For example, each memory cell at each intersection of the crossbar array may have memory cells of one or more bits, which may control the conductance of the corresponding intersection. Hereinafter, for convenience of description, the description of the array will be based on a ReRAM crossbar array. However, the array is not limited to a ReRAM crossbar array and may be an array having any of various crossbar array structures.

Thus, FIG. 2 shows how a convolution layer with four filters is mapped on a ReRAM crossbar array. Since representing more bits using a single cell may reduce noise margin and increase programming cost, two 2-bit cells may be used to represent a 4-bit weight in this example. Filters are placed horizontally to have all corresponding weights mapped to the same row, hence receiving the same input or activation value.

For example, a value of a weight may be indicated through resistive memory elements of the memory cells, and an input activation may be applied to each word line as a voltage source. Based on a bit precision of the weight and a number of bits per cell of the memory cell, respective weights of filters may be mapped to corresponding word lines of the array. More specifically, a weight at the same filter element position in a filter may be mapped to the same word line. For example, as illustrated in FIG. 2, each of weight 7 of Filter 0, weight 15 of Filter 1, weight 3 of Filter 2, and weight 12 of Filter 3 may be mapped to WL1.

A large portion of DNN weights can be zeroed-out without significant accuracy loss. However, it is challenging to turn this weight sparsity into real performance gains in typical accelerators due to their crossbar structures. For example, in FIG. 2, the 3rd through 8th cells on WL3 each have zero values. However, typically the corresponding non-zero values on WL4 of the crossbar array cannot be shifted up because the crossbar typically lacks fine-grained control on input-cell mappings (i.e., all cells attached to the same word line should typically receive the same input value). Thus, typically, since the positions of weights having a value of 0 are irregular in an example sparse DNN, there may be a case where almost no compression can be achieved because such typical example input-cell mappings may be performed for an entire row for all weights of all filters interacting with a same word line, or for an entire column for all weights of all filters interacting with a same bit line, as there are typically hundreds of weights in an entire row or entire column.

Rather, in various examples herein with sub-filter granularity, less than an entire row of consecutive weights that would have values of 0, e.g., at a predetermined position in each filter, if these consecutive weights were mapped to the crossbar, may still be compressed and these weights may not be mapped to the array, and thereby may provide a technological benefit of array reduction, cell reduction, and power reduction. For example, when a value of some of the weights in the same row are all 0 as shown in region 210 of FIG. 2, the corresponding weights may not be mapped to the array as a result of these weights being compressed.

According to one or more embodiments, methods and apparatuses/devices with neural network weight compression during implementation and/or training of the neural network may include compressing weights having a value of 0 by reordering a filter with sub-pixel granularity, and not mapping those compressed weights to a crossbar array, e.g., with maximal or increased compression of the filters with respect to weights that have values of 0.

Furthermore, according to various embodiments, an array may be respectively activated in an operation unit (OU), such as due to reliability and hardware limitations. For example, the illustrated 4*8 array of FIG. 2 may include 4 OUs, each having a size of 2*4, and as a result, 4 cycles in which a matrix-vector multiplication is executed may occur. For example, only a portion of a crossbar array, called the OU, or a crossbar of lesser rows (i.e., corresponding to the OU) than the entire number of weight elements in a filter, may be activated at the same time for reliable operations.

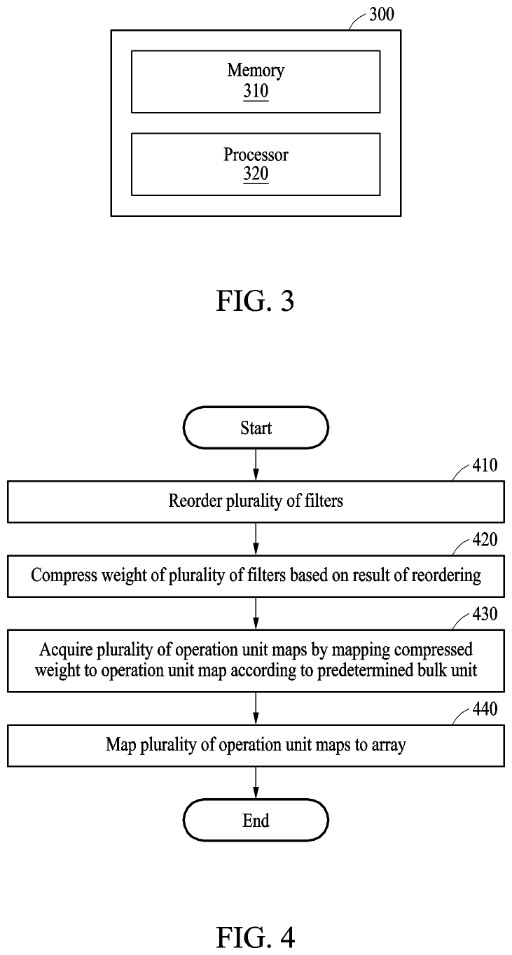

FIG. 3 is a block diagram illustrating an example computing apparatus with weight compression.

Referring to FIG. 3, a computing apparatus 300 may include a memory 310 and a processor 320. The memory 310 is representative of one or more memories, where some of the memories may be processor-in-memories or memories configured to perform processing operations such as one or more crossbar arrays. The processor 320 is also representative of one or more processors, and the processor 320 may also be representative of processor-in-memories or memories configured to perform processing operations such as one or more crossbar arrays.

The computing apparatus 300 may include the memory 310 and the processor 320 connected to the memory 310 through a system bus or another appropriate circuit.

The computing apparatus 300 corresponds to a device that performs compression on a weight of a neural network, e.g., performs compression on a sparse neural network. The computing apparatus may further perform pruning of weights of a trained neural network to the sparse neural network. For example, the computing apparatus 300 may correspond to, for example, a PC, a server device, and a mobile device, and furthermore, a computing apparatus included in, for example, an autonomous vehicle, a robotics, a smart phone, a table device, an augmented reality (AR) device, and an Internet of Things (loT) device, as non-limiting examples. In addition, the computing device may perform neural-network-based voice and/or image recognition using an accelerator or in-memory hardware that performs operations of one or more neural networks with weight compression, but examples may not be limited thereto.

The processor 320 is a hardware configuration that may perform overall control functions for controlling operations of the apparatus 300. For example, the processor 320 may generally control the computing apparatus 300 by executing programs (in the form of processor executable instructions, intermediate code, bytecode, interpretable/compilable source code, etc.) stored in the memory 310 in the computing apparatus 300. The processor 320 may be implemented as a central processing unit (CPU), a graphics processing unit (GPU), an application processor (AP), a neural processing unit (NPU), and the like, that are included in the computing apparatus 300, but examples are not limited thereto.

The computing apparatus 300 may store such programs in the memory 310. The processor 320 may implement an operation of compressing a neural network to reduce the number of zero value weights that are provided to a crossbar array by executing programs, for example, as well as implement an operation of pruning a neural network by executing other programs, respectively called from the memory 310 through the system bus.

The memory 310 may include a local memory or at least one physical memory device, such as at least one bulk storage device. Here, the local memory may include a random access memory (RAM), or other volatile memory devices generally used during actual execution of the program code. The bulk storage device may be implemented as a hard disk drive (HDD), a solid state drive (SSD), or other non-volatile memory devices. Also, the computing apparatus 300 may include at least one cache (not shown) that provides a temporary storage space of at least a partial program code to reduce a number of times bulk storage devices conduct a search for program code while performing a compression operation.

In response to the computing apparatus 300 executing an executable program stored in the memory 310, the processor 320 may be configured to perform one or more or all operations or methods described herein with respect to FIGS. 1-6.

Depending on a predetermined type of example computing apparatus represented by the computing apparatus 300, e.g., from among the non-limiting examples of a PC, a server device, and a mobile device, and furthermore, a computing apparatus as, or included in, for example, an autonomous vehicle, a robotics, a smart phone, a table device, an augmented reality (AR) device, and an Internet of Things (loT) device, the computing apparatus 300 may also include additional components than a number of components shown in FIG. 3. Also, in an example, at least one component may be included in another component and may constitute a portion of the other component.

Accordingly, in one or more examples, the processor 320 may increase a compression ratio by changing an order of the filters to pack weights into a compressible unit. In addition, the processor 320 may solve an issue of unbalancing in which a length of a predetermined filter remains longer than a length of other filters after compression, by reordering the filters and compressing the weights, mapping the weights according to a predetermined bulk unit, and then applying the reordering again to the unmapped weights, rather than reordering the filters once for an entire range.

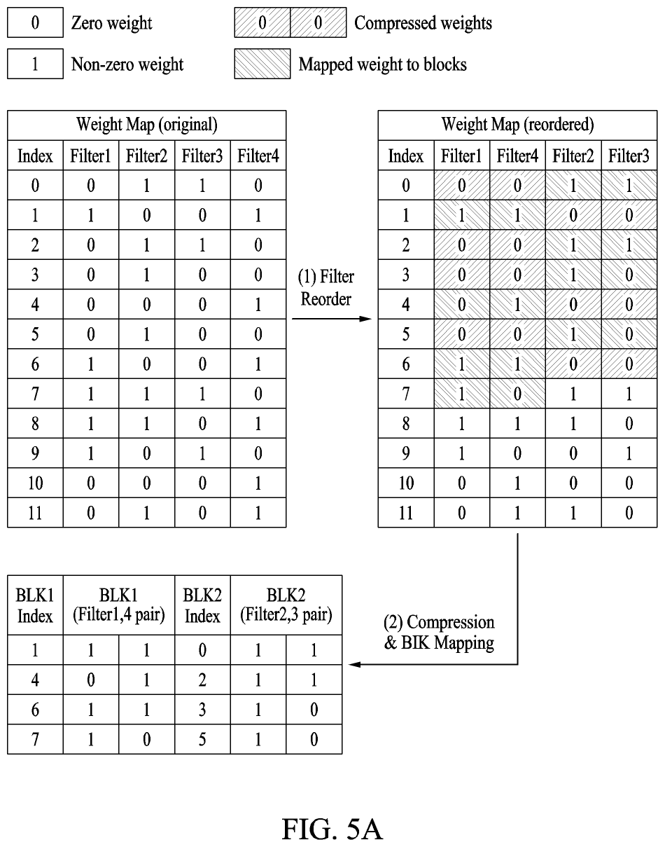

FIG. 4 is a flowchart illustrating an example method with weight compression.

Referring to FIG. 4, operations 410 to 440 may be performed by the computing apparatus 300 described above with reference to FIG. 3. Operations of FIG. 4 may be performed in the shown order and manner. However, the order of some operations may be changed, or some of the operations may be omitted, without departing from the spirit and scope of the shown example. The operations shown in FIG. 4 may be performed in parallel or simultaneously.

To improve array compression ratio in a non-limiting example ReRAM-based accelerator activated at an OU granularity, it may be desirable to make as many all-zero rows as possible within the OU. To this end, filter reordering can be adopted to cluster scattered zero weights. To effectively gather the zero weights, filters may be flexibly reordered horizontally at a sub-filter granularity. For example, dot-product computation may be performed at an OU granularity, where all weights along the column within an OU come from the same filter. Therefore, an OU-wise mapping strategy with OU-aware reordering at a sub-filter granularity may be performed. An example proposed mapping strategy first maps each slice of weights in a filter to an OU, and then this OU to a crossbar array. Since this OU-level sub-filter reordering provides much greater flexibility than filter-level reordering to produce additional all-zero OU rows, a much higher array compression ratio may be achieved.

In operation 410, the computing apparatus 300 reorders a plurality of filters. More specifically, the computing apparatus 300 may determine a base filter from among the plurality of filters, calculate a compression ratio between a base filter and the plurality of filters excluding the base filter in a bulk unit, and determine a filter to pair with the base filter based on a result of the calculating.

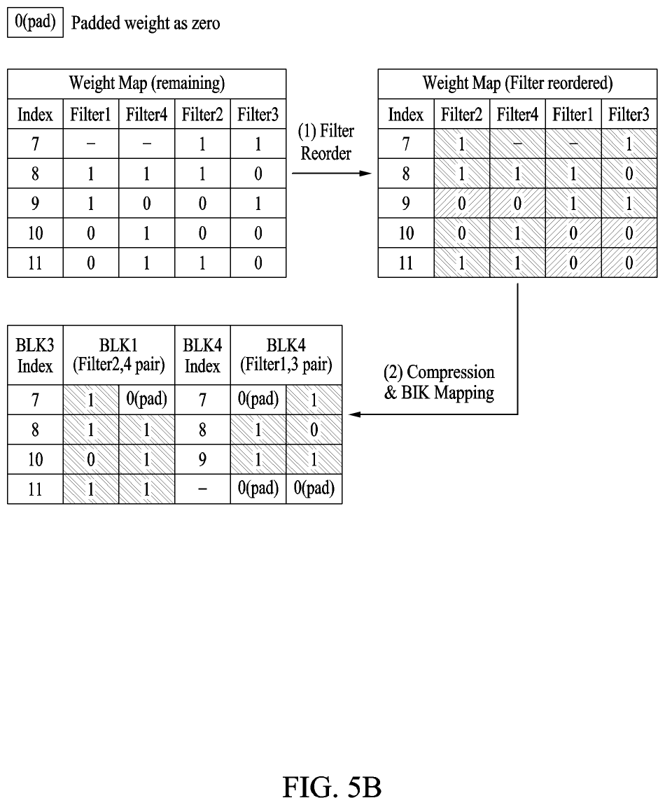

FIGS. 5A and 5B illustrate example methods with weight compression.

FIG. 5A presents a running example of the example weight mapping approach. The upper left table of FIG. 5A shows the weight mask of a given layer with the baseline, uncompressed mapping. In this weight mask, the value of 0 indicates a zero value weight (or pruned weight), and 1 indicates a non-zero weight. Corresponding weight indices are also shown in the leftmost column.

The computing apparatus 300 may reorder 4 filters (e.g., Filters 1 to 4) where an example first or only channel of each filter may include 12 weights (e.g., Indexed positions 0 to 11). The computing apparatus 300, for example, may first determine or select Filter 1 to be a base filter, and calculate a compression ratio between the base filter (e.g., Filter 1) and the remaining filters (e.g., Filters 2 through 4) in bulk units (e.g., in units of a 4*2 sized OU map, as a non-limiting example). Comparing Filter 1 and Filter 2 with respect to the first “4” rows, Indices 0-3, there is no compressible weight in the bulk unit, and comparing Filter 1 and Filter 3, only one row may be compressed because the weights of Index 3 in the bulk unit all have a value of 0, and comparing Filter 1 and Filter 4, three rows may be compressed because the weights of Indices 0, 2, and 3 all have a value of 0 in the bulk unit. Accordingly, the computing apparatus 300 may determine Filter 4 to be paired with Filter 1 for this OU.

In an example, a base filter may be set and a greedy search performed for a paired filter that would produce the most all-zero rows if the base filter was co-located at the same OU. This may produce as many all-zero rows in the OU as possible, hence maximizing the array compression ratio. The filter with the greatest number of unmapped weights remaining may be selected as the base filter to balance a compression ratio of all columns as much as possible.

The same filter pairing is performed for the remaining unpaired filters until all filters are paired. For example, the computing apparatus 300 may determine Filter 2 as a base filter, and Filter 3 as a paired filter of Filter 2.

Referring back to FIG. 4, in operation 420, the computing apparatus 300 compresses a weight of the plurality of filters based on a result of the reordering. The computing apparatus 300 may compress the weight of a base filter and paired filter based on a first direction. For example, with respect to the base filter and the pair filter, the computing apparatus 300 may perform a row compression where a row in which all elements have a predetermined weight value (e.g., 0) is provided.

After the filter reordering operation, all-zero rows may be compressed out at an OU granularity (i.e., the pair of co-located filters in FIG. 5A), whereas the non-zero rows are preserved for mapping to OUs. This process is continued until we get the same number of non-zero rows to map to a single OU. To take advantage of weight compression at a finer (sub-filter) granularity, instead of the granularity of the entire filter or shape, input indexing is desired. Moreover, since the ordering of filters may be same or different for each OU, output indexing may also be desirable. For example, with respect to FIG. 5A, starting from the reordered and paired filters (i.e., in the “Weight Map (reordered)” table), row compression for each pair may be performed. For example, all-zero value rows of either OU can be compressed out.

In operation 430, the computing apparatus 300 acquires a plurality of OU maps by mapping the uncompressed weights to an OU map according to a predetermined bulk unit.

Non-zero weights may be mapped to two OUs: Filter 1 and 4 to OU 1, and Filter 2 and 3 to OU 2. All-zero rows of either OU can be compressed out, and non-zero rows may be are copied over to the OU table illustrated below the weight maps in FIG. 5A

For example, the computing apparatus 300 may compress the weights of the rows corresponding to Indices 0, 2, and 3 in Filter 1 and Filter 4, and compress the weight of the row corresponding to Index 1 in Filter 2 and Filter 3.

The computing apparatus 300 may map the uncompressed weights (weights of Indices 1, 4, 6, and 7) of Filter 1 and Filter 4 to a 4*2 size OU map, and map the uncompressed weights (weights of Indices 0, 2, 3, and 5) of Filter 2 and Filter 3 to a 4*2 size OU map, to generate an OU map 1 BLK1 and an OU map 2 BLK2.

Referring to FIG. 5B, after the OU map 1 BLK1 and the OU map 2 BLK2 are generated, the computing apparatus 300 may move on to the next round of weights to repeat the same procedure for remaining weights that were not compressed out or not mapped to OU maps 1 and 2, by reordering and compressing remaining weights to generate an OU map 3 BLK3 and an OU map 4 BLK4.

More specifically, in the example of Filter 1 and Filter 4, the weight of Index 7 has already been mapped to OU map 1, but in the example of Filter 2 and Filter 3, the weight of Index 7 has not yet been mapped and the weight of Index 6 was compressed out. Accordingly, after the weight of Index 7 of Filter 1 and Filter 4 is padded with 0, the computing apparatus 300 may reorder the filters again.

For example, since the pairing of Filter 2 and 4 is determined to provide the most all-zero rows, the computing apparatus 300 may determine Filter 2 as a base filter and Filter 4 as a paired filter of Filter 2.

Similarly, the computing apparatus 300 may determine Filter 1 as a base filter and Filter 3 as a paired filter of Filter 1.

Thereafter, the computing apparatus 300 may compress the weight of the row corresponding to Index 9 in Filter 2 and Filter 4, and compress the weights of the rows corresponding to Indices 10 and 11 in Filter 1 and Filter 3.

The computing apparatus 300 may map the uncompressed weights (weights of Indices 7, 8, 10, and 11) of Filter 2 and Filter 4 to a 4*2 size OU map, and map the uncompressed weights (weights of Indices 7, 8, and 9) of Filter 1 and Filter 3 to a 4*2 size OU map, to respectively generate the OU map 3 BLK3 and the OU map 4 BLK4.

In operation 440, the computing apparatus 300 maps a plurality of OU maps to an array.

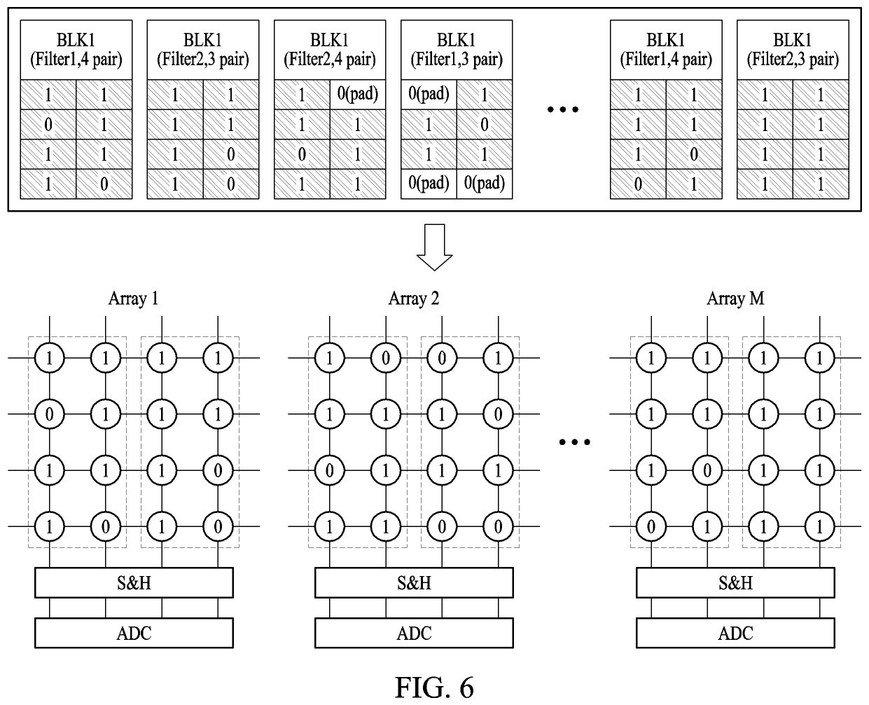

FIG. 6 illustrates an example method with plural OU mappings to an array or respective arrays.

Referring to FIG. 6, the computing apparatus 300 may map a plurality of OU maps to an array M respective cycles or to M separate arrays, as non-limiting examples. In an example with plural arrays, OU maps may be accumulated until a first array is full, and when the first array is full, remaining OU maps may be mapped to a subsequent array, etc., until all OU maps have been mapped to an array. For example, as illustrated in FIG. 6, OU maps 1 and 2 may be mapped to the first array, and OU maps 3 and 4 may be mapped to a second array.

According to one or more embodiments, since a weight may be compressed out, and thus not applied to an array, index information of the weight may be desired in order to feed the appropriate input activation corresponding to the weight. As described with reference to FIGS. 5A and 5B, the computing apparatus 300 may acquire index information of a plurality of filters, and determine index information of a plurality of OU maps based on the index information of the plurality of filters. The computing apparatus 300 may map the input activation to the array based on the index information of the plurality of OU maps.

The computing apparatuses, the electronic devices, the processors, the memories, and other apparatuses, devices, units, modules, and components described herein with respect to FIGS. 1-6 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-6 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD- Rs, DVD+Rs, DVD-RWs, DVD+RWs, DVD-RAMs, BD-ROMs, BD-Rs, BD-R LTHs, BD-Res, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

What is claimed is:

1. A processor-implemented method, the method comprising:
reordering a plurality of filters;
based on a result of the reordering, compressing weights, among a plurality of weights of the plurality of filters, resulting in some of the plurality of weights being uncompressed weights;
generating a plurality of operation unit maps by mapping the uncompressed weights to respective operation units according to a predetermined bulk unit; and
mapping the plurality of operation unit maps to an array.

2. The method of claim 1, wherein the reordering comprises:
determining a base filter from among the plurality of filters;
calculating a compression ratio between the base filter and one or more of the plurality of filters in the bulk unit; and
determining a filter paired with the base filter based on a result of the calculating, and
wherein the compressing includes compressing weights of the base filter and the paired filter that have a zero value at a same weight map position with respect to the base filter and the paired filter.

3. The method of claim 1, wherein the reordering comprises:
determining a base filter from among the plurality of filters; and
determining a filter, among the plurality of filters, that when paired with the base filter weights of the paired filter and the base filter is compressed most compared to respective pairings of the base filter with remaining filters of the plurality of filters.

4. The method of claim 1, wherein the compressing of the weights comprises compressing weights of a base filter and a paired filter, based on a first direction.

5. The method of claim 4, wherein the compressing of the weights comprises row compressing the weights of the base filter and the paired filter.

6. The method of claim 5, wherein the row compressing comprises compressing a row in which all elements have a predetermined weight value, among rows of the base filter and the paired filter.

7. The method of claim 1, wherein the generating of the plurality of operation unit maps comprises:
generating a first operation unit map with respect to some of the plurality of weights with respect to paired filters of the plurality of filters; and
after the generation of the first operation unit map, repeating the reordering and the compressing with respect to remaining weights of the plurality of weights with respect to other paired filters, to acquire a second operation unit map,
wherein the other paired filters include at least one same filter of the paired filters.

8. The method of claim 1, further comprising:
acquiring index information of the plurality of filters;
determining index information of the plurality of operation unit maps based on the index information of the plurality of filters; and
mapping respective input activations to the array based on the index information of the plurality of operation unit maps.

9. The method of claim 1, wherein the array comprises a resistive random access memory (ReRAM) having a crossbar array structure.

10. A non-transitory computer-readable storage medium storing instructions that, when executed by a processor, cause the processor to perform the method of claim 1.

11. An apparatus, the apparatus comprising:
a processor configured to:
reorder a plurality of filters;
based on a result of the reordering, compress weights, among a plurality of weights of the plurality of filters, resulting in some of the plurality of weights being uncompressed weights;
generate a plurality of operation unit maps by mapping the uncompressed weights to respective operation units according to a predetermined bulk unit; and
map the plurality of operation unit maps to an array.

12. The apparatus of claim 11, wherein, for the reordering, the processor is configured to:
determine a base filter from among the plurality of filters;
calculate a compression ratio between the base filter and one or more of the plurality of filters in the bulk unit; and
determine a filter paired to the base filter based on a result of the calculating, and
wherein, for the compressing, the processor is configured to compress weights of the base filter and the paired filter that have zero value at a same weight map position with respect to the base filter and the paired filter.

13. The apparatus of claim 11, wherein, for the reordering, the processor is configured to:
determine a base filter from among the plurality of filters; and
determine a filter, among the plurality of filters, that when paired with the base filter weights of the paired filter and the base filter is compressed most compared to respective pairings of the base filter and remaining filters of the plurality of filters.

14. The apparatus of claim 11, wherein, for the compressing, the processor is configured to:
compress weights of a base filter and a paired filter, based on a first direction.

15. The apparatus of claim 14, wherein, for the compressing, the processor is configured to:
row compress the weights of the base filter and the paired filter.

16. The apparatus of claim 15, wherein, for the compressing, the processor is configured to:
compress a row in which all elements have a predetermined weight value, among rows of the base filter and the paired filter.

17. The apparatus of claim 11, wherein, for the generating of the plurality of operation unit maps, the processor is configured to:
generate a first operation unit map with respect to some of the plurality of weights with respect to paired filters of the plurality of filters; and
after the generation of the first operation unit map, repeat the reordering and the compressing with respect to remaining weights of the plurality of weights with respect to other paired filters, to acquire a second operation unit map,
wherein the other paired filters include at least one same filter of the paired filters.

18. The apparatus of claim 11,
wherein the processor is configured to determine index information of the plurality of operation unit maps based on index information of the plurality of filters,
wherein, for the mapping, the processor is configured to map respective input activations to the array based on the index information of the plurality of operation unit maps, and
wherein the processor is further configured to implement a portion of a neural network to generate feature information, including application of the mapped respective input activations to the array.

19. An apparatus, the apparatus comprising:
a processor configured to:
perform a compression operation with respect to weights of a sparse neural network to remove zero valued weights with sub-filter granularity, including
performance of a reordering of plural filters into respective first pairs,
compression of zero value weights of respectively same weight map positions in each of the first pairs,
performance of another reordering of the plural filters into respective second pairs, and
compression of zero value weights of respectively same weight map positions in each of the second pairs.

20. The apparatus of claim 19, wherein the processor is further configured to generate feature information by the neural network by implementing plural crossbar arrays with uncompressed weights resulting from the performed compression operation, and
wherein some of the plural crossbar arrays are respectively mapped with different portions of uncompressed weights of a filter of the plural filters.
